(19) United States
(12) Patent Application Publication
(10) Pub. No.: US 2019/0044345 A1
(43) Pub. Date: Feb. 7, 2019

(54) CONTROL DEVICE AND METHOD FOR CHARGING A RECHARGEABLE BATTERY

(71) Applicant: TOYOTA MOTOR EUROPE, Brussels (BE)

(72) Inventors: Keita KOMIYAMA, Evere (BE); Yuki KATOH, Brussels (BE)

(73) Assignee: TOYOTA MOTOR EUROPE, Brussels (BE)

(21) Appl. No.: 16/076,565

(22) PCT Filed: Feb. 26, 2016
(86) PCT No.: PCT/EP2016/054048

§ 371 Date: Aug. 8, 2018

(51) Int. Cl. H02J 7/00; G01R 31/36

(52) U.S. Cl. CPC H02J 7/007; H02J 7/0029; H02J 2007/0037; G01R 31/3648; G01R 31/3679

(57) ABSTRACT

A control device for controlling charging of a rechargeable battery. The control device is configured to: determine the state of charge and the degradation of the battery before starting charging, determine a target charging curve based on the determined state of charge and degradation of the battery, the target charging curve indicating the target capacity as a function of the target voltage of the battery during charging, charge the battery thereby monitoring the capacity and the voltage of the battery, determine the voltage deviation between the target voltage and the monitored voltage based on the target charging curve and the monitored capacity, and stop charging, when the determined voltage deviation exceeds a predetermined threshold. The invention also refers to a corresponding method of controlling charging of a rechargeable battery.

### FIELD OF THE DISCLOSURE

The present disclosure is related to a control device for controlling charging of a rechargeable battery and also to a method of charging of a rechargeable battery.

### BACKGROUND OF THE DISCLOSURE

Rechargeable batteries, also called secondary cells, have become increasingly important as energy storages, in particular for vehicles. Such vehicles may be hybrid vehicles comprising an internal combustion engine and one or more electric motors or purely electrically driven vehicles.

A suitable rechargeable battery for such a vehicle may be an all solid-state bipolar battery or other, e.g. liquid type batteries, in particular a laminated Li-ion battery. The rechargeable battery may be realized by a single cell or it may include a set of preferably identical cells. In the latter case the battery is also called a battery pack.

A relevant characteristic of a battery is its capacity. A battery's capacity is the amount of electric charge it can deliver at a rated voltage. The more electrode material contained in the battery the greater is its capacity. The capacity is measured in units such as amp-hour (A·h).

The battery or the battery pack may include a control device for controlling charging and/or discharging. The control device monitors state of charge (SOC) of the battery and it shall avoid the battery from operating outside its safe operating area. Such a battery or battery pack is also called smart battery/smart battery pack. It is also possible that the control device is provided by the vehicle.

One important aspect of charge control is to assure that any overcharging and/or over-discharging of the battery is avoided. For this purpose the battery voltage may be monitored, which is increasing during charging. In case the determined battery voltage exceeds a predetermined upper voltage limit, it is recognized by the control device that the battery is fully charged and charging is stopped.

However, during the lifetime of a battery a micro short circuit between the positive and the negative electrode may occur. If a battery consists of only one non-laminated cell, i.e. the battery only comprises one positive and one negative electrode such a micro short circuit can be relatively easily recognized by monitoring the temperature and the voltage of the battery. In particular a micro short circuit can be determined based on a voltage decrease and a temperature increase of the battery.

Since a fully charged state of the battery is recognized based on comparing the monitored voltage during charging with a predetermined upper voltage limit, such a conventional charging control procedure can be disturbed by an occurred micro short circuit. The micro short circuit namely decreases the monitored voltage. Thus there is the risk of overcharging. Moreover there is the risk of overheating the battery due to the generated heat. It is therefore known to employ a security function in the charging control procedure, according to which a micro short circuit can be recognized and charging is stopped in this case.

However, in case of a all solid-state bipolar battery, in particular a laminated Li-ion battery, the electrodes are laminated in a multitude of levels, e.g. several hundred levels, in series. In such a case it is almost impossible or at least very difficult to monitor the voltage and the temperature for each and every layer.

JP2012095411 (A) discloses an internal short circuit detector for a secondary cell, which is monitoring self-discharged capacity when the cell is in a rest state, i.e. the cell is not charged or discharged. However, as a consequence this detector is not able to detect a micro short circuit during charging or discharging.

JP2010257984 (A) refers to a secondary battery system capable of detecting the status of the secondary battery system including abnormality of the secondary battery system. The secondary battery system is equipped with a dV/dQ calculation means to establish a dV/dQ, which is a ratio of a variation amount dV of a battery voltage V of the secondary battery to a variation amount dQ of a power storage amount Q when the power storage amount Q of the secondary battery changes. The system can detect a micro short circuit based on an overall shape change of the dV/dQ ratio. However, the system needs a multitude of charge/discharge cycles, i.e. a relatively long time, until the dV/dQ ratio is established and is ready for reliably detecting a micro short circuit.

### SUMMARY OF THE DISCLOSURE

Currently, it remains desirable to provide a control device which provides a charging control function including a reliable and economic security function for detecting micro short circuits, in particular in an all solid-state bipolar battery.

Therefore, according to embodiments of the present disclosure, a control device is provided for controlling charging of a rechargeable battery. The control device is configured to:
determine the state of charge and the degradation of the battery before starting charging,
determine a target charging curve based on the determined state of charge and degradation of the battery, the target charging curve indicating the target capacity as a function of the target voltage of the battery during charging,
charge the battery thereby monitoring the capacity and the voltage of the battery,
determine the voltage deviation between the target voltage and the monitored voltage based on the target charging curve and the monitored capacity, and
stop charging, when the determined voltage deviation exceeds a predetermined threshold.

By providing such a configuration it is possible to reliably detect a micro short circuit in the battery. Such a detection is possible during charging or discharging of the battery. In other words, charging or discharging does not need to be stopped, in order to detect a micro short circuit. Moreover, since the target charging curve can be determined already before the first use of the battery and the micro short circuit detection is based on a voltage monitoring during charging/discharging, a micro short circuit can be reliably detected from the first use in the battery's lifetime on.

The target charging curve preferably indicates the target relation between the capacity and the voltage of the battery during charging and preferably in a corresponding way during discharging. Said target charging curve thereby preferably relates to a battery without micro short circuits. Hence, any deviation of said target charging curve may be used to determine an abnormality of the battery, in particular one or more micro short circuits.

The voltage deviation between the target voltage and the monitored voltage is determined based on the target charging curve. This means that based on the currently measured (i.e. monitored) capacity the corresponding target capacity and hence the related target voltage may be found in the target charging curve. Said found target voltage may then be compared to the currently measured (i.e. monitored) voltage and the deviation between the values (i.e. the determined voltage deviation) can be determined.

The monitored capacity may be the current capacity increment of the voltage. Said current capacity increment may in particular define that amount of capacity which has already been charged since charging is started. For example, if charging is started at 40% SOC (i.e. the state of charge starting value) and the current SOC after starting charging is 60% SOC, the current capacity increment corresponds to 20% SOC. In a corresponding way, the target capacity may be a target capacity increment, in particular defining that amount of capacity which should have already been charged since charging is started. Generally, there may be no or only a minor difference between the value of the target capacity and the value of the actually monitored capacity.

The predetermined threshold may be set based on the voltage accuracy dispersion of the used voltage sensor. The predetermined threshold may have a fixed value. Alternatively, the predetermined threshold may have a changing value. For example, the predetermined threshold may continuously increase with an increasing capacity of the target charging curve. The predetermined threshold may be in particular a function of the capacity.

Whether or not the predetermined threshold may increase while charging desirably depends on how to set voltage accuracy dispersion. In case that this dispersion will be set at each voltage (each SOC), the predetermined threshold may be increased in accordance with current capacity (current SOC).

The control device and the procedure performed by the control device are suitable for all types of all solid-state bipolar batteries. However, the control device may also be applied to other battery types, like liquid type batteries, as e.g. Li-ion battery.

The control device may also be configured to control discharging of the rechargeable battery.

The control device may be further configured to:
store a plurality of predetermined target charging curves each relating to a different state of charge starting value, at which charging is started, and/or to a different degradation of the battery, and
determine a target charging curve by selecting a suitable target charging curve based on the determined state of charge and degradation of the battery.

Hence, a plurality of predetermined target charging curves may be provided, each relating to a specific degradation and a specific SOC starting value, and the suitable target charging curve can be selected based on the current degradation and SOC before charging is started. The state of charge starting value is that SOC value which the battery has before charging is started.

By providing such a configuration it is possible to determine the target charging curve already before the first use of the battery, such that is reliably operable from the beginning of the lifetime of the battery on.

The control device may comprise:
a rechargeable dummy cell,
a first circuit configured to charge the battery and the dummy cell, and
a second circuit configured to measure the open circuit voltage of the dummy cell.

The control device may be further configured to:
determine the open circuit voltage of the dummy cell by using the second circuit, and
determine the state of charge of the battery based on the determined open circuit voltage of the dummy cell.

By providing such a configuration it is possible to reliably determine the state of charge of the battery.

The dummy cell allows measuring the open circuit voltage more precisely than it could be done at the battery. Hence, also the maximum capacity increment of the battery can be determined more precisely. The dummy cell may consist of one single secondary (i.e. rechargeable) cell. It may be included in the battery (in particular if the battery is realized as a battery pack comprising a plurality of cells). Basically, the design parameters (as e.g. the cell capacity, the degradation rate or the cell type, etc.) may be same between the dummy cell and the battery. In particular, in case the battery is realized as a battery pack comprising a plurality of cells, the dummy cell may be of the same type as such a cell of the battery. The dummy cell may be configured only for supporting controlling charging of the rechargeable battery but not for driving the vehicle, in particular with regard to its stored electrical power. However, it may be charged and discharged in correspondence to the battery.

The open circuit voltage is the difference of electrical potential between two terminals of a device, i.e. between the two terminals of the dummy cell, when disconnected from any circuit, in particular the first circuit according to the disclosure. Hence, there is no external load connected, such that no external electric current flows between the terminals.

The control device may be further configured to:
determine the maximum capacity increment of the battery based on the determined state of charge of the battery.

By providing such a configuration it is possible to control charging based on capacity monitoring of the battery. Said maximum capacity increment of the battery is preferably the maximum chargeable capacity increment. More particularly, the maximum capacity increment is preferably that amount of capacity, which still remains to be charged until the battery is fully charged, advantageously until its state of charge (SOC) reaches 100%.

The capacity of a battery is the amount of electric charge it can deliver at a rated voltage. The capacity is measured in units such as amp-hour (A·h). The maximum capacity increment of the battery according to the disclosure represents the amount of electric charge which has to be charged, when charging is started. Hence, in case the state of charge SOC is e.g. 30% when charging is started, the maximum capacity increment of the battery corresponds to 70%. The maximum capacity increment of the battery may also be referred to as the Depth of Discharge (DOD) of the battery, which is the complement of SOC: as the one increases, the other decreases. The DOD may also be expressed in Ah.

The control device may further be configured to:
charge the battery and the dummy cell by using the first circuit,
monitor the current capacity increment of the battery which has been charged, and
stop charging, when the current capacity increment of the battery exceeds the determined maximum capacity increment.

Accordingly, the control device is able to reliably charge the battery based on the determined maximum capacity increment, until the battery is fully charged.

The control device may further be configured to determine, whether the battery is discharged during charging. If this is the case, the control device is preferably further configured to re-determine the open circuit voltage of the dummy cell by using the second circuit and to re-determine the maximum capacity increment and the state of charge of the battery based on the re-determined open circuit voltage. In this way the control device may be configured to consider a discharging of the battery which may happen at the same time, as the battery is charged. For instance, when the vehicle is driven by the electric motor which is fed by the battery, the battery is discharged. In case the vehicle is a hybrid vehicle, the battery may be charged at the same time by the electric power generated by the internal combustion engine. The control device may be configured to control charging and/or discharging of the battery.

The control device may further be configured to determine the current capacity increment of the battery based on the charging current and charging time of the battery, and/or based on the open circuit voltage of the dummy cell.

In other words, by integrating the current over time, the capacity of the battery may be calculated. Alternatively or additionally the capacity may be determined based on the open circuit voltage of the dummy cell. The current capacity increment may be measured while the battery is charging provided that the measurement is based on the charging current and charging time of the battery. In case the system uses measuring the voltage of the dummy cell during charging, the charging may stop shortly in order to measure the current capacity increment.

The control device may further be configured to determine the degradation of the battery based on a determined degradation of the dummy cell, wherein the degradation of the battery in particular corresponds to the determined degradation of the dummy cell.

Accordingly, the dummy cell may be also used to determine the degradation of the battery. In one example the degradation of the battery may be equal to the degradation of the dummy cell.

The degradation of the dummy cell may be determined based on a temperature/frequency distribution of the dummy cell and a predetermined degradation rate of the dummy cell.

The determination of the degradation of the dummy cell may be based on the Arrhenius equation.

The temperature/frequency distribution of the dummy cell may be determined by recording for each temperature of the dummy cell how much time the dummy cell had this temperature during its lifetime.

In other words, the temperature data of the dummy cell may be collected during the life time of the dummy cell, i.e. during its usage and the rests between usages. The temperature/frequency distribution may be established by accumulating for each temperature the dummy cell had during its past life time, how long the dummy cell had this temperature. For this reason it is advantageous that the dummy cell has the same age, i.e. lifetime, like the battery. In other words, the dummy cell is advantageously replaced, when the battery is replaced.

The control device may be configured determine the state of charge of the dummy cell based on the determined open circuit voltage of the dummy cell, and in particular based on a predetermined SOC-OCV mapping. Hence, the control device may be provided with a predetermined SOC-OCV mapping, e.g. a SOC-OCV curve, in which it may look up the SOC value, which corresponds to the measured OCV value. The predetermined SOC-OCV mapping may be updated based on the determined degradation of the dummy cell. Accordingly, said SOC-OCV mapping may be predetermined before the first charging of the dummy cell. It may further be updated during the charging procedures. Consequently, the maximum capacity increment of the battery may be determined based on the determined open circuit voltage of the dummy cell and the degradation of the dummy cell.

The control device may further be configured to determine the state of charge of the battery based on the determined state of charge of the dummy cell and in particular based on a predetermined mapping between the state of charge of the battery and the state of charge of the dummy cell. For example the control device may look-up in a predetermined look-up table, i.e. the predetermined mapping, the state of charge of the battery which matches to the determined state of charge of the dummy cell.

The control device may moreover be configured to determine the maximum capacity increment based on the state of charge of the battery. Hence, the relationship between the maximum capacity increment and the determined state of charge of the battery may be calculated by the control device. In other words, the maximum capacity increment of the battery may be determined based on the determined state of charge of the battery, which itself has been determined based on the determined state of charge of the dummy cell, which itself has been determined based on the determined open circuit voltage of the dummy cell and the determined degradation of the dummy cell.

The control device may be configured to control charging of a battery of a specific battery type comprising a predetermined degradation rate, wherein the dummy cell may have a degradation rate which correlates with the degradation rate of the battery, and which in particular may be the same degradation rate. Accordingly, the dummy cell may also be a rechargeable battery. The dummy cell is preferably chosen such that, based on its measured characteristics, the characteristics of the battery can be determined. In particular, the dummy cell is chosen such that, based on its determined degradation rate, the degradation rate of the battery and hence also a suitable maximum capacity increment of the battery can be determined.

Moreover, the battery of the specific battery type preferably comprises a predetermined capacity, wherein the dummy cell may have a capacity which correlates with the capacity of the battery. For example, in case the battery is a battery pack comprising a plurality of cells, the dummy cell may have the same capacity as such a cell. Furthermore, the dummy cell may be of the same type as such a dummy cell. Accordingly, the dummy cell is chosen such that, based on its state of charge, the state of charge of the battery and hence also a suitable maximum capacity increment of the battery can be determined. For example, if the vehicle uses the battery between SOC20% and SOC80%, the dummy cell may have the capacity which is equivalent to this range, i.e. may also have a range between SOC20% and SOC80%.

Preferably, the control device may comprise a voltage sensor for detecting the open circuit voltage of the dummy cell. The control device may comprise a further voltage sensor for detecting the voltage and/or the state of charge of the battery.

The control device may comprise a temperature sensor for detecting the temperature of the dummy cell and/or the battery.

The disclosure further relates to a battery pack. The battery pack may comprise at least one battery, in particular a solid state bipolar battery, and a control device as described above.

The disclosure further relates to a battery charging system. Said battery charging system may comprise at least one battery, in particular a solid state bipolar battery, a charging device for the battery, and a control device as described above.

According to a further aspect the disclosure relates to a vehicle comprising an electric motor and a battery pack, as described above.

Alternatively the vehicle may comprise an electric motor, at least one battery, in particular a solid state bipolar battery, and in addition a control device, as described above.

Moreover the disclosure relates to a method of controlling charging of a rechargeable battery. The method comprises the steps of:
determining the state of charge and the degradation of the battery before starting charging,
determining a target charging curve based on the determined state of charge and degradation of the battery, the target charging curve indicating the target capacity as a function of the target voltage of the battery during charging,
charging the battery thereby monitoring the capacity and the voltage of the battery,
determining the voltage deviation between the target voltage and the monitored voltage based on the target charging curve and the monitored capacity, and
stopping charging, when the determined voltage deviation exceeds a predetermined threshold.

The method may further comprise the steps of:
storing a plurality of predetermined target charging curves each relating to a different state of charge starting value, at which charging is started, and/or to a different degradation of the battery, and
determining a target charging curve by selecting a suitable target charging curve based on the determined state of charge and degradation of the battery.

Furthermore in the method a first circuit may be used to charge the battery and a rechargeable dummy cell, and a second circuit may be used to measure the open circuit voltage of the dummy cell. The method may further comprise the steps of:
determining the open circuit voltage of the dummy cell by using the second circuit, and
determining the state of charge of the battery based on the determined open circuit voltage of the dummy cell.

The method may further comprise the steps of:
determining the maximum capacity increment of the battery based on the determined state of charge of the battery.

The method may further comprise the steps of:
charging the battery and the dummy cell by using the first circuit,
monitoring the current capacity increment of the battery which has been charged, and
stopping charging, when the current capacity increment of the battery exceeds the determined maximum capacity increment.

The current capacity increment of the battery may be determined based on the charging current and charging time of the battery, and/or based on the open circuit voltage of the dummy cell.

The degradation of the battery may be determined based on a determined degradation of the dummy cell, wherein the degradation of the battery in particular corresponds to the determined degradation of the dummy cell.

The degradation of the battery may be determined based on a temperature/frequency distribution of the dummy cell and a predetermined degradation rate of the dummy cell.

The determination of the degradation of the dummy cell may be based on the Arrhenius equation.

The temperature/frequency distribution of the dummy cell may be determined by recording for each temperature of the dummy cell how much time the dummy cell had this temperature during its lifetime.

The accompanying drawings, which are incorporated in and constitute a part of this specification, illustrate embodiments of the disclosure and together with the description, serve to explain the principles thereof.

### BRIEF DESCRIPTION OF THE DRAWINGS

FIG. 1 shows a schematic representation of a vehicle comprising a control device according to an embodiment of the present disclosure;

FIG. 2 shows a schematic representation of the electric circuits of the control device according to an embodiment of the present disclosure;

FIG. 3 shows a flow chart of the general charging control procedure according to an embodiment of the present disclosure;

FIG. 4 shows a flow chart of the procedure for updating a SOC-OCV curve according to an embodiment of the present disclosure;

FIG. 5 shows an exemplary and schematic diagram of a SOC-OCV curve;

FIG. 6 shows an exemplary and schematic diagram of a predetermined degradation rate in relation to the temperature of a dummy cell;

FIG. 7 shows an exemplary and schematic diagram of a determined temperature/frequency distribution of a dummy cell;

FIG. 8 shows an exemplary and schematic capacity-voltage diagram of a battery, where several target charging curves according to an embodiment of the present disclosure are indicated.

FIG. 9 shows an exemplary and schematic voltage-SOC diagram of a battery, when a conventional charging control is applied;

FIG. 10 shows an exemplary and schematic capacity-voltage diagram of a battery, when a charging control according to an embodiment of the present disclosure is applied.

### DESCRIPTION OF THE EMBODIMENTS

Reference will now be made in detail to exemplary embodiments of the disclosure, examples of which are illustrated in the accompanying drawings. Wherever possible, the same reference numbers will be used throughout the drawings to refer to the same or like parts.

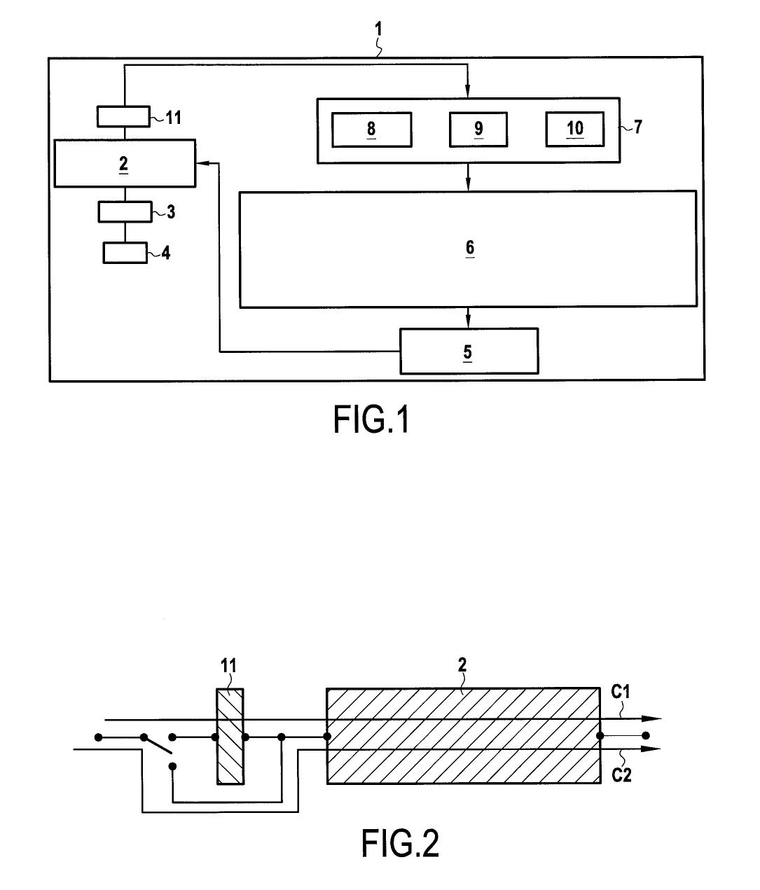

FIG. 1 shows a schematic representation of a vehicle 1 comprising a control device 6 according to an embodiment of the present disclosure. The vehicle 1 may be a hybrid vehicle or an electric vehicle (i.e. a purely electrically driven vehicle). The vehicle 1 comprises at least one electric motor 4, which is powered by a battery or battery pack 2, preferably via an inverter 3. In case the vehicle is a hybrid vehicle, it further includes an internal combustion engine. The battery 2 may be a solid-state bipolar battery. However, it may also be another battery type, like a liquid type battery, as e.g. a Li-ion battery.

The battery 2 is connected to a charging unit 5 which is configured to charge the battery 2. For this purpose the charging unit 5 may comprise an electric control circuit, as e.g. a power electronics circuit. The charging unit may further comprise or be connected to a connector for external charging by an external power source. The connector may be e.g. a plug or a wireless connector system. In case the vehicle is a hybrid vehicle, the charging unit may further be connected to the electrical generator of the internal combustion engine of the vehicle. Consequently, the battery 2 may be charged, when the internal combustion engine is operating and/or when the vehicle is connected to an external power source. Furthermore the battery 2 may be discharged, in order to operate the vehicle 1, in particular the electric motor 4. The battery 2 may further be discharged in a battery treatment and/or recovery procedure.

The vehicle further comprises a dummy cell 11 which is configured to provide information, in particular measurements, based on which the charging of the battery 2 is controlled. This will be described in more detail below. The dummy cell 11 may be a further rechargeable battery, preferably of the same type as the battery 2. It may be integrated into the vehicle, e.g. it may be integrated with the control device 6. Alternatively it may be integrated with the battery 2. In the latter case the dummy cell 11 can be easily replaced together with the battery 2. For example, the battery may be realized as a battery pack comprising a plurality of cells, wherein the dummy cell is realized as a cell of the same type and may be included in the battery pack.

In order to control charging and discharging the vehicle 2 is provided with the control device 6 and sensors 7. For this purpose the control device 6 monitors the battery 2 and/or the dummy cell 2 via the sensors 7 and controls the charging unit 5. The control device 6 and/or the sensors 7 may also be comprised by the battery 2. The control device may be an electronic control circuit (ECU). It may also comprise a data storage. It is also possible that the vehicle comprises a smart battery charging system with a smart battery and a smart charging device. In other words, both the battery and the vehicle may comprise each an ECU which operate together and form together the control device according to the disclosure. In the latter case the dummy cell 11 may be integrated in the smart battery. Furthermore the control device 6 may comprise or may be part of a battery management system.

The control device 6 may comprise an application specific integrated circuit (ASIC), an electronic circuit, a processor (shared, dedicated, or group), a combinational logic circuit, a memory that executes one or more software programs, and/or other suitable components that provide the described functionality of the control device 6.

As it will be explained in more detail in the following, the sensors 7 comprise in particular a voltage sensor 10 for measuring the open circuit voltage (OCV) of the dummy cell 11. Moreover the sensors 7 may comprise one or more temperature sensors 8 for measuring the temperature of the battery 2 and/or the dummy cell 11, at least one SOC (state of charge) sensor 9 for measuring the state of charge of the battery 2 and/or the dummy cell 11 and at least one further voltage sensor 10 for measuring the voltage of the battery 2 and/or the dummy cell 11. The SOC sensor 9 may also be a voltage sensor, wherein the measured voltage is used to determine the SOC of the battery. Of course, the SOC sensor 9 may also comprise other sensor types to determine the SOC of the battery, as it is well known in the art.

FIG. 2 shows a schematic representation of the electric circuits of the control device according to an embodiment of the present disclosure. The dummy cell 11 and the battery 2 are connected to a first electrical circuit C1, for example in series. This circuit C1 is configured to charge both the dummy cell 2 and the battery 2. Preferably the circuit C1 is also configured to discharge both the dummy cell 2 and the battery 2. A second circuit C2 is configured to measure the open circuit voltage OCV_{d} of the dummy cell. In order to switch between the circuits C1 and C2, there may be provided a switch, which can be controlled by the control device 6. It is noted that FIG. 2 is a simplified diagram of the electric circuits of the control device.

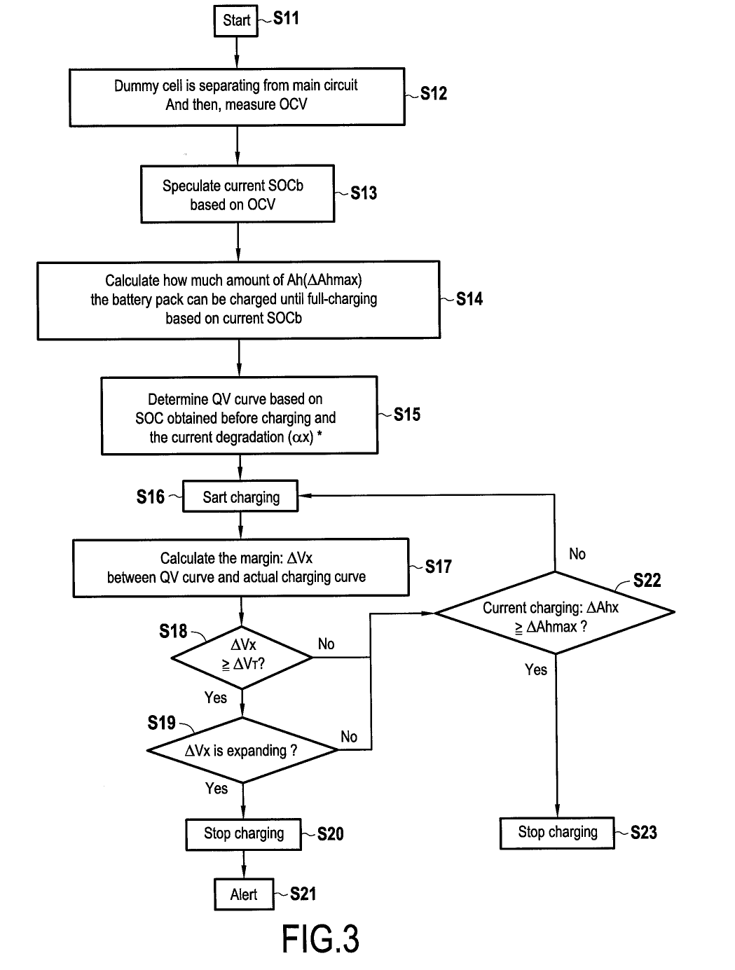

FIG. 3 shows a flow chart of the general charging control procedure according to an embodiment of the present disclosure. The control device 6 is configured to carry out this procedure of FIG. 3.

In step S11 the procedure is started. The start may be triggered by a determination of the control device that charging of the battery is necessary (e.g. due to a low SOC) and/or by the fact that charging becomes possible (e.g. due to operation of the internal combustion engine or due to a connection to an external electrical power source).

In step S12 the dummy cell 11 is separated from the main charging circuit C1. In other words the control device will switch to circuit C2, in which the dummy cell 11 is separated from the circuit C1. Subsequently the open circuit voltage OCV_{d} of the dummy cell is measured.

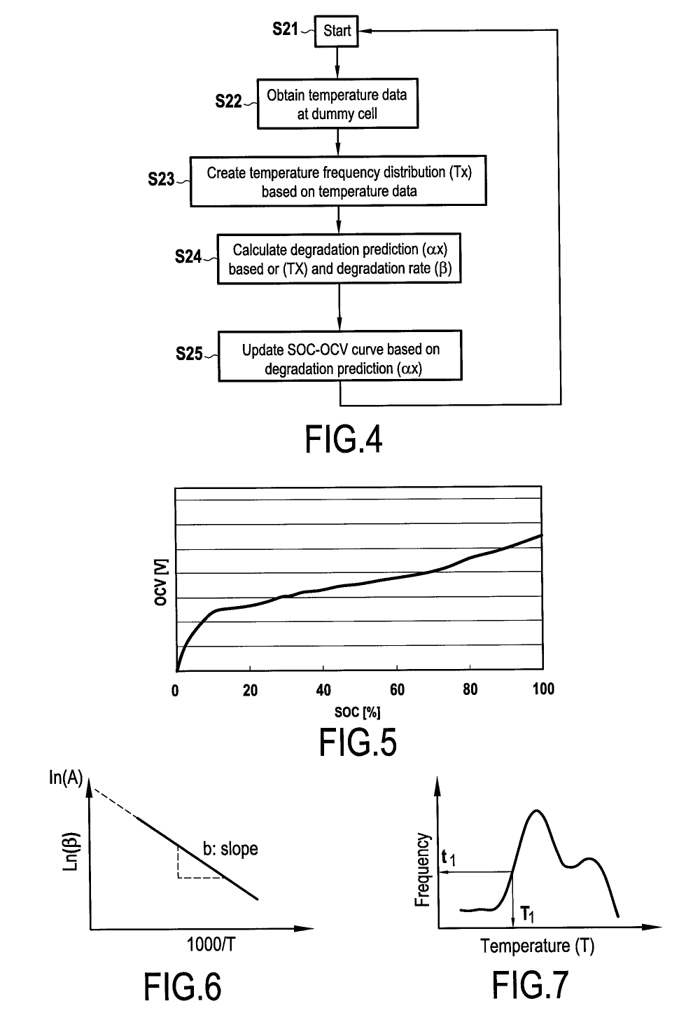

In step S13 the current state of charge SOC_{d} of the dummy cell is determined based on the measured open circuit voltage of the dummy cell 11. Since this determination of SOC_{d} may not be exact, it may also be referred to as a speculated value. In addition, the state of charge SOC_{d} of the dummy cell may be determined based the determined degradation of the dummy cell, as it will be explained in detail in context of FIG. 4. Furthermore the state of charge SOC_{b} of the battery is determined based on the state of charge SOC_{d} of the dummy cell 11. In order to do so, a predetermined mapping may be used which indicates the relationship between the SOC_{d} of the dummy cell 11 and the SOC_{b} of the battery.

In step S14 the maximum capacity increment ΔAhₘₐₓ of the battery is determined, basically based on the open circuit voltage OCV_{d} of dummy cell and advantageously the determined degradation αₓ of the dummy cell. The determined degradation αₓ of the dummy cell preferably corresponds to that one of the battery or has a known relationship to that one of the battery.

In particular, the maximum capacity increment ΔAhₘₐₓ of the battery may be determined based on the determined state of charge SOC_{d} of the dummy cell 11, which is determined in step S13 based on the open circuit voltage and the degradation of the dummy cell. In addition, the maximum capacity increment ΔAhₘₐₓ of the battery 2 may be determined based on a predetermined SOC-OCV mapping by identifying in the SOC_{d} value which matches to the measured OCV_{d} value. The SOC-OCV mapping may be regularly updated based on the determined degradation αₓ of the dummy cell, as it will be explained in detail in context of FIG. 4. The SOC-OCV mapping may be represented by a SOC-OCV curve, as shown in FIG. 5.

More particularly, the maximum capacity increment ΔAhₘₐₓ of the battery may be determined based on the state of charge SOC_{b} of the battery, which itself is determined based on the state of charge SOC_{d} of the dummy cell 11. In order to do so, a predetermined mapping may be used which indicates the relationship between the SOC_{d} of the dummy cell 11 (as determined in step S13) and the SOC_{b} of the battery. For example, the maximum capacity increment ΔAhₘₐₓ of the battery may be calculated based on the difference between 100% SOC (determined based on the current degradation αₓ) and the determined current SOC_{b} (determined based on the current degradation αₓ), i.e.

ΔAhₘₐₓ=SOC100%(αₓ)−SOC_{b}(αₓ)

The procedure of steps S13 to S14 preferably only takes a limited time, as e.g. 0.02 s, 0.05 s, 0.1 s, 0.2 s or 1 s.

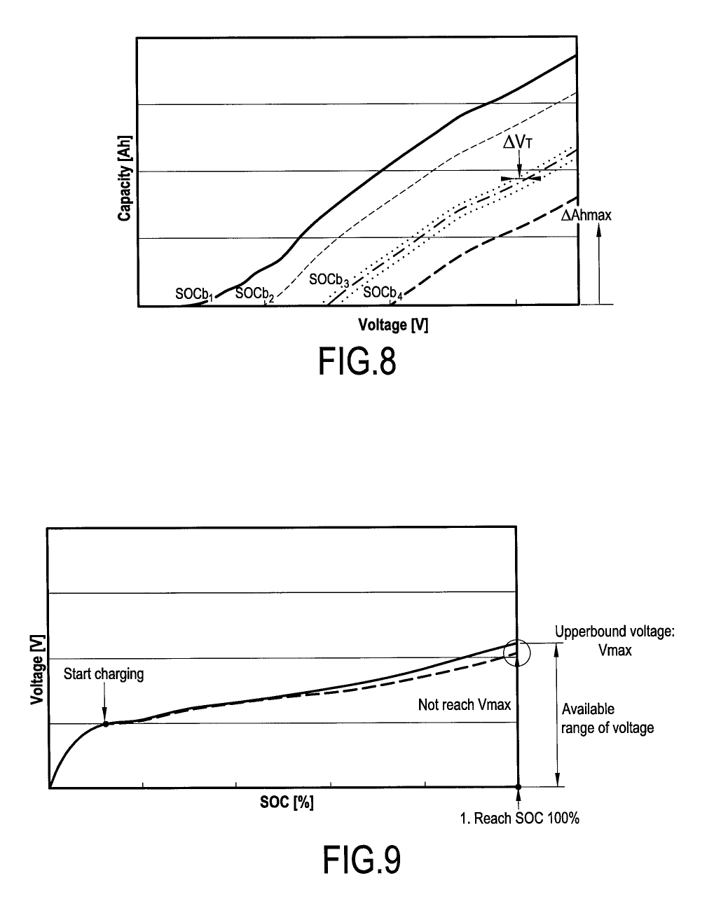

In step S15 the target charging curve is determined based on the determined state of charge SOC_{b} and the degradation α_{b} of the battery. The degradation α_{b} of the battery may be determined based on the determined degradation α_{d} of the dummy cell, advantageously it may be the same degradation. The target charging curve may be determined by selecting a suitable one of a plurality of predetermined and stored target charging curves. The selection may be based on the determined state of charge SOC_{b} and the degradation α_{b} of the battery, as it will be explained in detail in context of FIG. 8. The target charging curve provides information about a target capacity and a target voltage of the battery during charging.

In step S16 charging is started. This is done by switching to circuit C1. During charging the voltage of the battery and the current capacity increment ΔAhₓ of the battery are monitored, i.e. both parameters are regularly measured.

Said current capacity increment ΔAhₓ of the battery may be determined based on the monitored charging current Iₓ and the charging time of the battery, in particular based on the measured charging current Iₓ integrated over the charging time. Additionally or alternatively the current capacity increment ΔAhₓ of the battery may be determined based on a previously measured open circuit voltage of the dummy cell.

In step S17, based on the current voltage and the current capacity increment ΔAhₓ of the battery, the voltage deviation (ΔVₓ) between currently measured voltage and the target voltage, which is derived from the target charging curve based on the currently measured capacity increment ΔAhₓ, is determined.

In step S18 it is determined, whether the determined voltage deviation ΔVₓ exceeds a predetermined threshold ΔV_{T}. Said threshold ΔV_{T} indicates a maximally allowable deviation of the actual voltage of the battery compared to the target voltage derived from the target charging curve. For example the predetermined threshold ΔV_{T} may be 0.02% of the voltage of the battery in fully charged state. This means that, when the battery has e.g. 300 V when it is fully charged, the predetermined threshold ΔV_{T} may be +/−0.6 V. It is noted that ΔVₓ and ΔV_{T} are preferably absolute (i.e. positive) values.

In case the determined voltage deviation ΔVₓ exceeds the predetermined threshold ΔV_{T}, it may be further determined in step S19, whether the voltage deviation ΔVₓ is expanding, in particular during charging. In order to accurately detect whether a micro short circuit has occurred, this additional step S19 may be implemented in the method. ΔVx increases while the battery is charging, if a micro short circuit occurs. Therefore, the accuracy to detect a micro short circuit may be increased by additionally determining, whether ΔVₓ is expanding.

It should further be noted that the additional control step of S20 may be useful because there is also the possibility to surpass threshold ΔV_{T} due to malfunction of the voltage sensor (this malfunction means that the sensor cannot guarantee the accuracy). In this case, the control device may require another evaluation criteria, whether or not a micro short circuit occurs, as e.g. the control step of S19.

In order to decide in step S19, whether ΔVₓ is expanding, the control device may store, desirably for a charge cycle, the development of ΔVₓ during charging. In other words, the control device may know the development of ΔVₓ in a charge cycle. Based on such data of ΔVₓ it may be determined, whether the currently determined ΔVₓ expands in comparison with the previously determined ΔVₓ which has been determined in the same charge cycle right before at a lower capacity charge state. For example, if the currently determined ΔVₓ has been determined at a capacity charge state corresponding to 70% SOC, the previously determined ΔVₓ serving as reference may be that value corresponding to 69% SOC.

Alternatively, in order to decide in step S19, whether ΔVₓ is expanding, the control device may store, desirably for each charge cycle, the development of ΔVₓ during charging. Based on such history data of ΔVₓ it may be determined, whether the currently determined ΔVₓ expands in comparison with the previously determined ΔVₓ. The previously determined ΔVₓ, which is taken as comparison reference, may be the corresponding ΔVₓ value of the last charge cycle, in particular at the same capacity level.

Of course, as long as the voltage sensor works properly and accurately, the control step of S19 can be omitted. In other words, the control device may detect a micro short circuit by merely controlling, whether ΔVₓ exceeds ΔV_{T} (cf. step S18).

In case the determined voltage deviation ΔVₓ exceeds the predetermined threshold ΔV_{T}, and in particular if also the voltage deviation ΔVₓ is expanding, an abnormality state of the battery, in particular the presence of at least one micro short circuit is detected. Charging is stopped in this case in step S20.

Moreover an alert, i.e. a warning, may be output in step S21. This alert may inform the driver about the abnormal state of the battery.

However, in case the determined voltage deviation ΔVₓ does not exceed the predetermined threshold ΔV_{T} in step S18, and optionally also in case the voltage deviation ΔVₓ is not expanding in step S19, charging is continued.

Furthermore in these cases the method continues with step S22, it is determined, whether the current capacity increment ΔAhₓ of the battery exceeds the maximum capacity increment ΔAhₘₐₓ. The battery 2 is hence charged by returning to step S16, as long as the current capacity increment ΔAhₓ of the battery does not exceed the determined maximum capacity increment ΔAhₘₐₓ. Consequently the control procedure runs a loop S16, S17, S18, (and optionally S19) and S22 during charging, where regularly the current capacity increment ΔAhₓ of the battery is determined (i.e. monitored) in step S22 and regularly the voltage deviation ΔVₓ is determined (i.e. monitored).

Otherwise, in case the current capacity increment ΔAhₓ of the battery exceeds the determined maximum capacity increment ΔAhₘₐₓ in step S22, the charging procedure is completed and finally stopped in step S23.

FIG. 4 shows a flow chart of the procedure for updating a SOC-OCV curve (i.e. a SOC-OCV mapping) according to an embodiment of the present disclosure. An exemplary and schematic diagram of a SOC-OCV curve is shown in FIG. 5.

The procedure of FIG. 4 is preferably carried out in step S13 of the procedure of FIG. 3 so that the SOC-OCV curve and hence the maximum capacity increment ΔAhₘₐₓ is always determined based on a currently updated degradation αₓ. It is noted that the determined degradation αₓ rather represents an estimation of the actual degradation of the battery.

In step S22 temperature data of the dummy cell are obtained. For this purpose the temperature sensor 8 may be used. However, these data may include not only the current temperature of the dummy cell, but also historic temperature data since the last time the procedure of FIG. 4 has been carried out, in particular since the last time the temperature frequency distribution Tₓ has been updated (cf. step S23).

In step S23 the temperature frequency distribution Tₓ is established or, in case a temperature frequency distribution Tₓ already exists, it is updated. For this purpose the collected temperature data obtained in step S22 are accumulated, wherein the accumulated time for each measured temperature is expressed as its inverse, i.e. as frequency. The temperature frequency distribution Tₓ is described in more detail below in context of FIG. 7.

In step S24 the degradation αₓ of the dummy cell is determined based on the temperature frequency distribution Tₓ and the predetermined dummy cell specific degradation rate β, which preferably corresponds, in particular is equal, to the battery-type specific degradation rate β. This determination, i.e. calculation, is described in the following with reference to FIGS. 6 and 7.

Basically the calculation of the degradation αₓ is based on the Arrhenius equation, as generally known in the art. The degradation αₓ is calculated by

$$α x = c \times exp ( \frac{b}{T} ) \times T$$

$$wherein \text{:}$$

$$t = time$$

$$c = ln ( A )$$

$$b = - ( E / R )$$

$$T = Temperature$$

The current degradation αₓ is thereby an accumulated value, i.e. the currently calculated degradation and the sum of all formerly calculated degradations, as e.g.:

αx1=α₁+α₂+α₃ . . .

with:

$${α}_{1} = c \times exp ( \frac{b}{{T}_{1}} ) \times {t}_{1}$$

The values for the temperature T and for the time t can thereby be derived from the temperature frequency distribution Tₓ as shown in FIG. 7. The further parameters c and b are predetermined in context of the determination of the degradation rate β.

The degradation rate β is calculated based on the equation:

$$k = A exp ( - \frac{{E}_{a}}{RT} )$$

wherein:
k=predetermined reaction rate constant (or rate constant)
A=constant
Eₐ=activation energy
R=gas constant

### T=Temperature

The parameters k, A, Ea and R are known by pre-experiment of the specific type of the used dummy cell, which preferably corresponds to the type of the battery, or are generally known parameters.
When k⇒β:

$$ln ( β ) = ln ( A ) - ( \frac{E}{R} ) \times \frac{1}{T}$$

Accordingly, the parameters b and c for the calculation of degradation αₓ can be determined by:
b=−(E/R)
c=ln(A)
The resulting diagram of the degradation rate β is shown in FIG. 6. The degradation rate β is predetermined and specific for the type of the used dummy cell, which preferably corresponds to the type of the battery. The degradation rate β is preferably determined in pre-experiment and is known by the battery (in case of a smart battery) and/or by the control device.

The SOC_{b} of the battery may be mapped to the SOC_{d} of the dummy cell, which itself is mapped (e.g. by way of the SOC-OCV mapping) to the determined degradation αₓ in a look-up map, i.e.:

αₓ₁⇒SOC_{d1}⇒SOC_{b1}

αₓ₂⇒SOC_{d2}⇒SOC_{b2}

αₓ₃⇒SOC_{d3}⇒SOC_{b3}

αₓ₄⇒SOC_{d4}⇒SOC_{b4}

etc.

This relation between SOC_{d} and αx and/or between SOC_{b} and SOC_{d} is preferably determined in a pre-experiment and is specific for the battery-type of the used dummy cell, which preferably corresponds to the battery-type of the battery 2. The look-up map may be stored in a data storage of the control-device or of the battery (in case of a smart battery).

FIG. 5 shows an exemplary and schematic diagram of a SOC-OCV curve. As it can be seen, the OCV values are successively increasing with increasing SOC. Hence, for each OCV value a unique SOC value can be determined from the SOC-OCV curve. The SOC-OCV curve is preferably predetermined in experiments before the battery is used. During the lifetime of the battery the battery SOC-OCV curve may be continuously updated, at least once per charging procedure described in context of FIG. 3.

FIG. 6 shows an exemplary and schematic diagram of a predetermined degradation rate in relation to the temperature of a dummy cell. As it can be seen the values of the parameters b and c can be directly derived from this diagram, as b is the slope of the linear function and c is the intercept of the (elongated) linear function with the Y-axis.

FIG. 7 shows an exemplary and schematic diagram of a determined temperature/frequency distribution of a dummy cell. In the diagram the x-axis represents the temperature T of the dummy cell and the y-axis represents the frequency, i.e. the inverse of the time. The diagram contains the accumulated temperature data of the dummy cell over its whole life time, i.e. over the whole time the dummy cell has been used and the rest times between the usages. In order to establish the diagram, i.e. the illustrated curve, it is determined for each temperature the dummy cell had during its life time, e.g. from −40° C. to +60° C. in (quantized) steps of 1° C., how much time the dummy cell had each of these temperatures. The accumulated time is thereby expressed by its inverse, i.e. by a frequency. Preferably, the life time of the dummy cell corresponds to that one of the battery 2. The temperature of the dummy cell should approximately correspond to that one of the battery, so that their degradation is the same. Accordingly, the dummy cell may be positioned close to the battery. Also both the dummy cell and the battery may be positioned in a case of a battery pack. This case may be equipped with a cooling fan and/or means for stabilizing the temperature of the dummy cell and the battery. Thereby, the temperature of the dummy cell and the battery can become equal.

FIG. 8 shows an exemplary and schematic capacity-voltage diagram of a battery, where several target charging curves according to an embodiment of the present disclosure are indicated.

The diagram shows four target charging curves, which relate to the same battery having a certain degradation. However, the four target charging curves relate do different state of charge (SOC_{b}) starting values, SOC_{b1} (e.g. 10%), SOC_{b2} (e.g. 20%), SOC_{b3} (e.g. 30%), SOC_{b4} (e.g. 40%). This means that, in case the battery has 20% SOC when charging is started, the target charging curve relating to SOC_{b2} is preferably selected. Even if this example only shows four different target charging curves for a range between e.g. 10% and 40%, it is noted that there may be provided more target charging curves, in particular for covering the complete possible SOC range between 0% and 100%. Also the resolution may be different than 10% SOC, e.g. also every 5% SOC a target charging curve may be provided.

In a corresponding way, for each state of charge (SOC_{b}) starting value a plurality of target charging curves relating to different degradations may be provided. A suitable target charging curve may then be selected also based on the determined current degradation of the battery.

All these target charging curves are preferably determined in a pre-experiment for the specific battery type and stored in the control device.

In case the currently determined SOC is between two of the provided state of charge (SOC_{b}) starting values (e.g. 32%), a suitable target charging curve may be obtained by linear interpolation of the closest of the provided target charging curves and/or by determining a weighted average of the two adjacent target charging curves.

In FIG. 8 it is indicated the predetermined threshold ΔV_{T} range (by dotted lines left and right to the target charging curve) of the target charging curve relating to 30% SOC_{b} (the target charging curve indicated as alternating dotted/dashed line). The predetermined threshold ΔV_{T} range is determined by adding and subtracting the predetermined threshold ΔV_{T} to and from the target charging curve. In case the actually measured charging curve exceeds this predetermined threshold ΔV_{T} range, a micro short circuit can be detected.

FIG. 9 shows an exemplary and schematic voltage-SOC diagram of a battery, when a conventional charging control is applied. As it can be seen the voltage V of the battery increases during charging, i.e. it increases with an increasing SOC of the battery.

The continuous line thereby represents a battery without any micro short circuit. The measured voltage V of such a battery reaches during charging the upper voltage limit Vₘₐₓ, when the SOC reaches 100%. As an effect, it is correctly determined that charging is completed and charging is stopped.

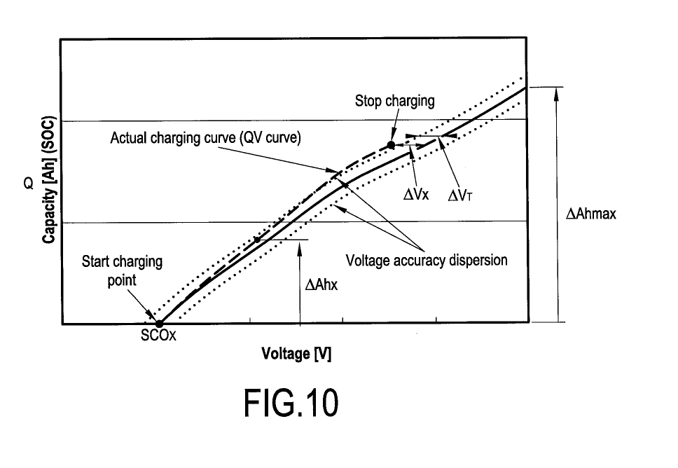

The dashed line represents a battery with one or more micro short circuits. The measured voltage V of such a battery increases less strongly during charging due to the micro short circuits. The voltage V therefore reaches a value lower than the upper voltage limit Vₘₐₓ, when the SOC is about 100%. As an effect, it is erroneously determined that charging is not yet completed and charging is continued what may lead to dangerous over charging. This can be avoided by the present disclosure as described in context of FIG. 10.

FIG. 10 shows an exemplary and schematic capacity-voltage diagram of a battery, when a charging control according to an embodiment of the present disclosure is applied. FIG. 10 illustrates a corresponding case as FIG. 9, i.e. a battery with one or more micro short circuits (cf. dashed line).

Moreover in the diagram the target charging curve is indicated which is suitable for the SOC starting value of the battery and the current degradation of the battery (cf. continuous line). Moreover the predetermined threshold ΔV_{T} range is indicated (by dotted lines left and right to the target charging curve). The predetermined threshold ΔV_{T} range is determined by adding and subtracting the predetermined threshold ΔV_{T} to and from the target charging curve, e.g. 0.2% of the voltage of the battery in fully charged state may. This means that, when the battery has e.g. 300 V when it is fully charged, the predetermined threshold ΔV_{T} may be +/−0.6 V. The size of the predetermined threshold ΔV_{T} may be chosen depending on the accuracy of the accuracy of the used sensors. Consequently, with an increasing accuracy of the used sensors the predetermined threshold ΔV_{T} may be decreased. In this example, the predetermined threshold ΔV_{T} is chosen to be a constant value for the whole charge cycle. However, the predetermined threshold ΔV_{T} may also be a changing value, in particular a value which increases together with the current capacity increment ΔAhₓ.

The current capacity increment ΔAhₓ preferably corresponds to that amount of capacity which has been added during charging to the state of charge (SOC_{b}) starting value during charging, i.e. to the charged capacity. In case the measured voltage exceeds the predetermined threshold ΔV_{T} range, i.e. the voltage deviation ΔVₓ between the target voltage and the monitored voltage exceeds the threshold ΔV_{T}, a micro short circuit in the battery can be detected and charging may be stopped. Hence, dangerous overcharging and also dangerous overheating during charging can be avoided.

In the present example, the voltage deviation ΔVₓ between the target voltage and the monitored voltage exceeds the threshold ΔV_{T}. However, charging is not stopped immediately. This is due to the reason that charging is only stopped, when ΔVₓ is expanding (cf. also step S19 of FIG. 3). In this example this is detected based on a comparison of the currently determined ΔVₓ (of current execution of step S17 in FIG. 3) with the previously determined ΔVₓ (of preceding execution of step S17 in the preceding loop of steps S16, S17, S18, S19, S22 of FIG. 3).

Throughout the disclosure, including the claims, the term “comprising a” should be understood as being synonymous with “comprising at least one” unless otherwise stated. In addition, any range set forth in the description, including the claims should be understood as including its end value(s) unless otherwise stated. Specific values for described elements should be understood to be within accepted manufacturing or industry tolerances known to one of skill in the art, and any use of the terms “substantially” and/or “approximately” and/or “generally” should be understood to mean falling within such accepted tolerances.

Where any standards of national, international, or other standards body are referenced (e.g., ISO, etc.), such references are intended to refer to the standard as defined by the national or international standards body as of the priority date of the present specification. Any subsequent substantive changes to such standards are not intended to modify the scope and/or definitions of the present disclosure and/or claims.

Although the present disclosure herein has been described with reference to particular embodiments, it is to be understood that these embodiments are merely illustrative of the principles and applications of the present disclosure.

It is intended that the specification and examples be considered as exemplary only, with a true scope of the disclosure being indicated by the following claims.

1. A control device for controlling charging of a rechargeable battery, the control device being configured to:
determine the state of charge and the degradation of the battery before starting charging,
determine a target charging curve based on the determined state of charge and degradation of the battery, the target charging curve indicating the target capacity as a function of the target voltage of the battery during charging,
charge the battery thereby monitoring the capacity and the voltage of the battery,
determine the voltage deviation between the target voltage and the monitored voltage based on the target charging curve and the monitored capacity, and
stop charging, when the determined voltage deviation exceeds a predetermined threshold.

2. The control device according to claim 1, further configured to:
store a plurality of predetermined target charging curves each relating to a different state of charge starting value, at which charging is started, and/or to a different degradation of the battery, and
determine a target charging curve by selecting a suitable target charging curve based on the determined state of charge and degradation of the battery.

3. The control device according to claim 1, comprising:
a rechargeable dummy cell,
a first circuit configured to charge the battery and the dummy cell, and
a second circuit configured to measure the open circuit voltage of the dummy cell,
the control device being further configured to:
determine the open circuit voltage of the dummy cell by using the second circuit, and
determine the state of charge of the battery based on the determined open circuit voltage of the dummy cell.

4. The control device according to claim 3, further configured to:
determine the maximum capacity increment of the battery based on the determined state of charge of the battery.

5. The control device according to claim 4, further configured to:
charge the battery and the dummy cell by using the first circuit, monitor the current capacity increment of the battery which has been charged, and
stop charging, when the current capacity increment of the battery exceeds the determined maximum capacity increment.

6. The control device according to claim 5, further configured to:
determine the current capacity increment of the battery based on the charging current and the charging time of the battery, and/or based on the open circuit voltage of the dummy cell.

7. The control device according to claim 2, further configured to determine the degradation of the battery based on a determined degradation of the dummy cell, wherein the degradation of the battery in particular corresponds to the determined degradation of the dummy cell.

8. The control device according to claim 7, further configured to determine the degradation of the dummy cell based on a temperature/frequency distribution of the dummy cell and a predetermined degradation rate of the dummy cell.

9. The control device according to claim 7, wherein
the determination of the degradation of the dummy cell is based on the Arrhenius equation.

10. The control device according to claim 8, further configured to determine the temperature/frequency distribution of the dummy cell by recording for each temperature of the dummy cell how much time the dummy cell had this temperature during its lifetime.

11. The control device according to claim 2, configured to control charging of a battery of a specific battery type comprising a predetermined degradation rate,
wherein the dummy cell has a degradation rate which correlates with the degradation rate of the battery, and which in particular is the same degradation rate.

12. The control device according to claim 11, wherein the battery of the specific battery type comprises a predetermined capacity,
wherein the dummy cell has a capacity which correlates with the capacity of the battery, and which in particular is the same capacity.

13. The control device according to claim 2, comprising a voltage sensor for detecting the open circuit voltage of the dummy cell.

14. The control device according to claim 2, comprising a temperature sensor for detecting the temperature of the dummy cell and/or the battery.

15. A battery pack comprising:
at least one battery, in particular a solid state bipolar battery, and
a control device according to claim 1.

16. A battery charging system comprising:
at least one battery, in particular a solid state bipolar battery,
a charging device for the battery, and
a control device according to claim 1.

17. A vehicle comprising:
an electric motor, and
a battery pack according to claim 15.

18. A vehicle comprising:
an electric motor,
at least one battery, in particular a solid state bipolar battery, and
a control device according to claim 1.

19. A method of controlling charging of a rechargeable battery, the method comprising the steps of:
determining the state of charge and the degradation of the battery before starting charging,
determining a target charging curve based on the determined state of charge and degradation of the battery, the target charging curve indicating the target capacity as a function of the target voltage of the battery during charging,
charging the battery thereby monitoring the capacity and the voltage of the battery,
determining the voltage deviation between the target voltage and the monitored voltage based on the target charging curve and the monitored capacity, and
stopping charging, when the determined voltage deviation exceeds a predetermined threshold.

20. The method according to claim 19, further comprising the steps of:
storing a plurality of predetermined target charging curves each relating to a different state of charge starting value, at which charging is started, and/or to a different degradation of the battery, and
determining a target charging curve by selecting a suitable target charging curve based on the determined state of charge and degradation of the battery.

21. The method according to claim 20, wherein a first circuit is used to charge the battery and a rechargeable dummy cell, and a second circuit is used to measure the open circuit voltage of the dummy cell, the method comprising the steps of:
determining the open circuit voltage of the dummy cell by using the second circuit, and
determining the state of charge of the battery based on the determined open circuit voltage of the dummy cell.

22. The method according to claim 21, further comprising:
determining the maximum capacity increment of the battery based on the determined state of charge of the battery.

23. The method according to claim 22, further comprising the steps of:
charging the battery and the dummy cell by using the first circuit,
monitoring the current capacity increment of the battery which has been charged, and
stopping charging, when the current capacity increment of the battery exceeds the determined maximum capacity increment.

24. The method according to claim 23, wherein the current capacity increment of the battery is determined based on the charging current and the charging time of the battery, and/or based on the open circuit voltage of the dummy cell.

25. The method according to claim 20, wherein the degradation of the battery is determined based on a determined degradation of the dummy cell, wherein the degradation of the battery in particular corresponds to the determined degradation of the dummy cell.

26. The method according to claim 25, wherein the degradation of the battery is determined based on a temperature/frequency distribution of the dummy cell and a predetermined degradation rate of the dummy cell.

27. The method according to claim 25, wherein the determination of the degradation of the dummy cell is based on the Arrhenius equation.

28. The method according to claim 26, wherein the temperature/frequency distribution of the dummy cell is determined by recording for each temperature of the dummy cell how much time the dummy cell had this temperature during its lifetime.
